(19) United States
(12) Patent Application Publication
(10) Pub. No.: US 2024/0109206 A1
(43) Pub. Date: Apr. 4, 2024

(54) CHIP INSTALLATION AND REMOVAL TOOL

(71) Applicant: Quantinuum LLC, Broomfield, CO (US)

(72) Inventor: Garrett Zerba, Glenwood Springs, CO (US)

(21) Appl. No.: 18/451,939

(22) Filed: Aug. 18, 2023

Related U.S. Application Data
(60) Provisional application No. 63/411,360, filed on Sep. 29, 2022.

(51) Int. Cl. B25J 15/10; H01L 21/677; H01L 21/687

(52) U.S. Cl. CPC B25J 15/10; H01L 21/677; H01L 21/68707

(57) ABSTRACT

An installation and removal tool and a method of using the tool are provided, including for installing and removing semiconductor devices, such as computer chips. The tool may comprise a tool body comprising a plurality of tool body sides and a plurality of tool body projections, wherein each of the plurality of tool body sides includes at least one tool body projection. The tool may further comprise a plurality of fingers, wherein each of the plurality of fingers is pivotally coupled to one or more tool body projections via one or more pivots. Each of the plurality of fingers may be configured to be moveable via the pivot between a first position and a second position, the first position associated with a first stop on the associated finger and the second position associated with a second stop on the associated finger.

### CROSS-REFERENCE TO RELATED APPLICATIONS

The present application claims the benefit of U.S. Provisional Patent Application Ser. No. 63/411,360, which was filed on Sep. 29, 2022, the entire contents of which is incorporated by reference herein for all purposes.

### TECHNICAL FIELD

Various embodiments relate to a tool for installing and removing semiconductor devices and the like, including for installing and removing traps in quantum computers.

### BACKGROUND

Semiconductor devices, such as computer chips, often include pin grid arrays used for connecting the semiconductor device into a complementary socket. Installation and removal of semiconductor devices create problems due to the small size of the semiconductor device and how little space typical semiconductor devices have to allow for installation and removal. For example, conventional semiconductor removal tools have incorporated screws for applying leverage to pull out a semiconductor device from the underside of the device. However, such conventional tools include multiple parts that need to be assembled before use. Alternative methods of removing a semiconductor device included using a screw driver or lever to leverage a semiconductor device loose, but such methods risk damaging the semiconductor device and the socket it is installed in due to the leverage being applied over a small area. Through applied effort, ingenuity, and innovation, deficiencies of prior conventional semiconductor device installation and removal tools and methods have been solved by developing solutions that are structured in accordance with the embodiments of the present invention, many examples of which are described in detail herein.

### BRIEF SUMMARY OF EXAMPLE EMBODIMENTS

Example embodiments provide apparatuses, methods, and/or the like for an installation and removal tool. For example, various embodiments provide apparatuses, methods, and/or the like for an installation and removal tool for use in installing and/or removing a computer chip, a semiconductor device, and/or the like.

In an example embodiment, and according to an aspect of the present disclosure, a tool is provided. In some instance the tool comprises a tool body comprising a plurality of tool body sides and a plurality of tool body projections, wherein each of the plurality of tool body sides includes at least one tool body projection; a plurality of fingers, wherein each of the plurality of fingers is pivotally coupled to one or more tool body projections via one or more pivots; and wherein each of the plurality of fingers is configured to be moveable via the pivot between a first orientation and a second orientation, the first orientation is associated with a first stop on the associated finger; and the second orientation is associated with a second stop on the associated finger.

In some instances, each tool body side includes two tool body projections associated with one of the plurality of fingers.

In some instances, each tool body side is associated with two of the plurality of fingers.

In some instances, each pivot extends through a length of a finger to connect one of the plurality of fingers and at least two tool body projections.

In some instances, one or more fingers include an exterior protrusion configured to rotate the finger.

In some instances, one or more fingers includes a cavity configured for use with a second tool to rotate the finger.

In some instances, the first stop and the second stop of each finger are configured for use with one of a plurality of plungers.

In some instances, each of the first stop and the second stop of each finger comprise an aperture.

In some instances, each plunger comprises a spring, and wherein the spring of each plunger is configured to be adjusted to increase a spring tension of the associated plunger.

In some instances, the spring of each plunger is configured to be adjusted by an associated set screw.

In some instances, the tool body includes an interior cavity comprised of a plurality of corners, and wherein each of the corners is configured to have a corner chamber configured to accommodate a semiconductor device corner.

In some instances, the tool body is hollow.

In some instances, the plurality of tool body sides comprises four tool body sides.

In some instances, the plurality of fingers comprises one finger associated with each of the tool body sides.

In some instances, each of the fingers comprises a first finger extension configured engage a first surface to allow for the finger to rotate.

In some instances, each of the fingers is further configured to be moveable via the pivot associated with the finger in response to the associated finger extension engaging the first surface.

In accordance with another aspect of the present disclosure, a method for removing a semiconductor device is provided. In an instance, the method comprises: providing a tool comprising: a tool body comprising a plurality of tool body sides and a plurality of tool body projections, wherein each of the plurality of tool body sides includes at least one tool body projection; a plurality of fingers, wherein each of the plurality of fingers is pivotally coupled to one or more tool body projections via one or more pivots; and wherein each of the plurality of fingers is configured to be moveable via the pivot between a first orientation and a second orientation, the first orientation is associated with a first stop on the associated finger; and the second orientation is associated with a second stop on the associated finger; aligning the tool with the semiconductor device; pushing the tool onto the semiconductor device and an associated surface; orienting, in response to pushing the tool, each of the fingers to a grasping orientation, wherein the fingers in the grasping orientation include the fingers grasping the semiconductor device; removing the semiconductor device. In some instances, the method further comprises moving, after removing the semiconductor device, the fingers to an open orientation to release the semiconductor device from the tool.

In accordance with another aspect of the present disclosure, a method for installing a semiconductor device is provided. The method comprises: providing a tool comprising: a tool body comprising a plurality of tool body sides and a plurality of tool body projections, wherein each of the plurality of tool body sides includes at least one tool body projection; a plurality of fingers, wherein each of the plurality of fingers is pivotally coupled to one or more tool body projections via one or more pivots; and wherein each of the plurality of fingers is configured to be moveable via the pivot between a first orientation and a second orientation, the first orientation is associated with a first stop on the associated finger; and the second orientation is associated with a second stop on the associated finger; inserting the semiconductor device into the tool; moving the fingers to a grasping orientation; aligning the tool with a socket; and installing the semiconductor device into the socket. In some instances, the method further comprises moving, after installing the semiconductor device, the fingers to an open orientation.

The foregoing brief summary is provided merely for purposes of summarizing some example embodiments illustrating some aspects of the present disclosure. Accordingly, it will be appreciated that the above-described embodiments are merely examples and should not be construed to narrow the scope of the present disclosure in any way. It will be appreciated that the scope of the present disclosure encompasses many potential embodiments in addition to those summarized herein, some of which will be described in further detail below.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 illustrates and installation and removal tool in accordance with one or more embodiments of the present disclosure;

FIG. 2A illustrates a cross section of a tool with fingers in a first orientation in accordance with one or more embodiments of the present disclosure;

FIG. 2B illustrates a cross section of a tool with fingers in a second orientation in accordance with one or more embodiments of the present disclosure.

FIG. 3 illustrates a bottom view of a tool in accordance with one or more embodiments of the present disclosure.

FIG. 4A illustrates a finger from a first perspective in accordance with one or more embodiments of the present disclosure.

FIG. 4B illustrates a first end of a finger in a first orientation in accordance with one or more embodiments of the present disclosure.

FIG. 4C illustrates a first end of a finger in a second orientation in accordance with one or more embodiments of the present disclosure.

FIG. 5A illustrates a tool body projection from a first perspective in accordance with one or more embodiments of the present disclosure.

FIG. 5B illustrates a tool body projection from a second perspective in accordance with one or more embodiments of the present disclosure.

FIG. 6 illustrates a flow chart according to an example method for removing a semiconductor device in accordance with one or more embodiments of the present disclosure.

FIG. 7 illustrates a flow chart according to an example method for installing a semiconductor device in accordance with one or more embodiments of the present disclosure.

### DETAILED DESCRIPTION OF SOME EXAMPLE EMBODIMENTS

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally,” “substantially,” and “approximately” refer to within engineering and/or manufacturing tolerances and/or within user measurement capabilities, unless otherwise indicated. Like numbers refer to like elements throughout.

### Exemplary Installation and Removal Tool

Example embodiments provide apparatuses and/or the like for an installation and removal tool. For example, various embodiments provide apparatuses and/or the like for a trap installation and removal tool for use with quantum computers and quantum computing systems.

An installation and removal tool 100 may also be referred to herein as tool 100. While the tool 100 described herein may be described to be used to install and/or remove a semiconductor device having a pin grid array, it will be readily appreciated that the tool 100 may be utilized to install or remove other types of devices, including but not limited to devices where uniform application of pressure on a device in one or more areas may be beneficial to installing or removing the device.

In various embodiments, a tool 100 may be used to remove test equipment associated with a quantum computer. The test equipment may include one or more processor chips that are installed into a printed circuit board (PCB) socket via a pin grid array on each processor chip. The processor chip, when installed, may take, for example, 10 lbs. of pressure to dislodge from the socket. Conventional methods to remove such chips involved using a lever, but this would apply pressure at a point or a line, which may cause one or more pins to bend and/or a chip to be damaged.

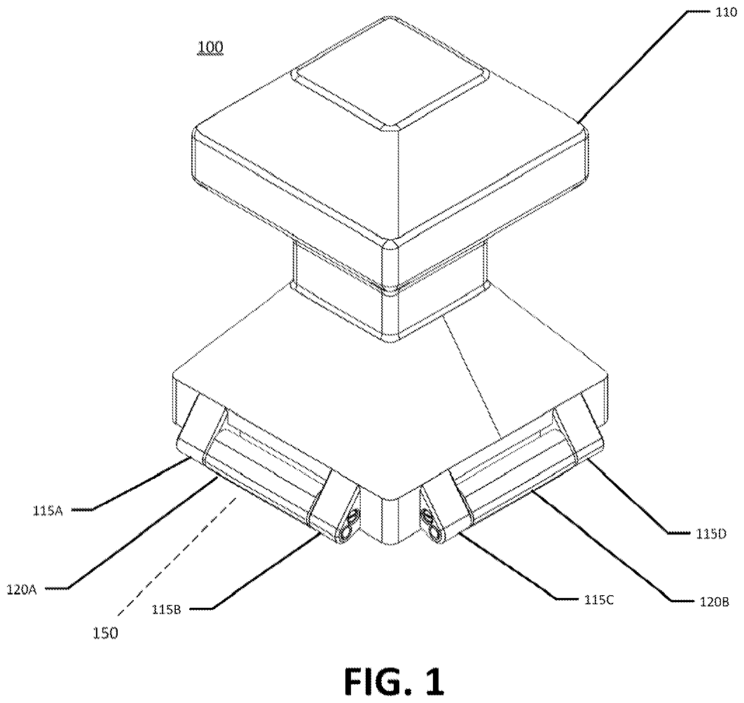

FIG. 1 illustrates and installation and removal tool 100 in accordance with one or more embodiments of the present disclosure. FIG. 1 is a perspective tool and illustrates two sides of an illustrated embodiment having four sides. Each of the sides, as is illustrated in this embodiment, may be symmetrical. The tool 100 includes a plurality of tool body projections 115 and fingers 120. In FIG. 1, four tool body projections 115A, 115B, 115C, and 115D are illustrated, and two fingers 120A and 120B are illustrated. Each of these fingers 120A and 120B are coupled or connected to two of the tool body projections 115A, 115B, 115C, and 115D, which is described further herein. In particular, finger 120A is coupled or connected to tool body projections 115A and 115B, and finger 120B is coupled or connected to tool body projections 115C and 115D. Also as described further herein, these couplings or connections allow for a finger 120 to be configured to rotate or cam about a pivot or pivot point. In various embodiments, when a first portion of a finger extension 122 is pushed against another surface, such as a PCB, the force opposing the finger 120 will cause the finger 120 to rotate or cam from a first orientation to a second orientation, which may be respectively referred to as from an open orientation to a grasping orientation. The finger extension 122 may be configured to engage a surface to allow the engagement to cause the finger to rotate. For example, the finger may be configured with a finger extension at an angle such that pushing against the surface causes the finger 120 to rotate or cam inwards.

In the illustrated embodiment of FIG. 1, the tool body 110 is in the form of a handle grip at a first end at the top of the illustration that is configured to be easy to grasp by a user as well as be pushed on by a user, which will evenly distribute pressure in a downwards direction of FIG. 1. As described herein, a user applying pressure via the tool body 100 against a surface will cause the fingers 120 of the tool 100 to rotate to grasp a semiconductor device, which will allow for the semiconductor device to be removed from where it is installed. The pressure downwards causing the finders 120 to grasp the semiconductor device include the fingers rotating to pry the semiconductor device from its installation. Once the fingers 120 have grasped the semiconductor device, a user may use the tool body 110 to lift the tool 100 and the semiconductor device, which would remove a semiconductor device from its socket.

In various embodiments, the tool body 110 may be made of plastic and/or metal, such as stainless steel. In various embodiments, the tool body 110 may be printed with a 3D printer to take various shapes. The interior of the tool body 110 may be hollow, which may decrease the weight of the tool 100 and, if 3D printing is used to create the tool body 110, may reduce the amount of material required to 3D print the tool body 110. Alternatively, the tool body 110 may be a solid piece of material.

In various embodiments not illustrated, the tool body 110 may take various shapes that may be configured for a user's grip and/or configured for a space available for the tool 100 to be used in. This may include the tool body 110 to have one or more angles or bends. In various embodiments, the tool body 110 may be comprised of multiple tool body portions that may be connected, such as screwed together via threads or secured together with screws, glue, epoxy, or the like.

In various embodiments, a tool 100 may include fingers 120 on each side of the tool 100. Alternatively, a tool 100 may include more than one finger 120 per side (e.g., 2 fingers per side, 3 fingers per side, etc.) or may include only certain sides of the tool 100 with fingers 120, which may have some sides of the tool 100 without a finger 120.

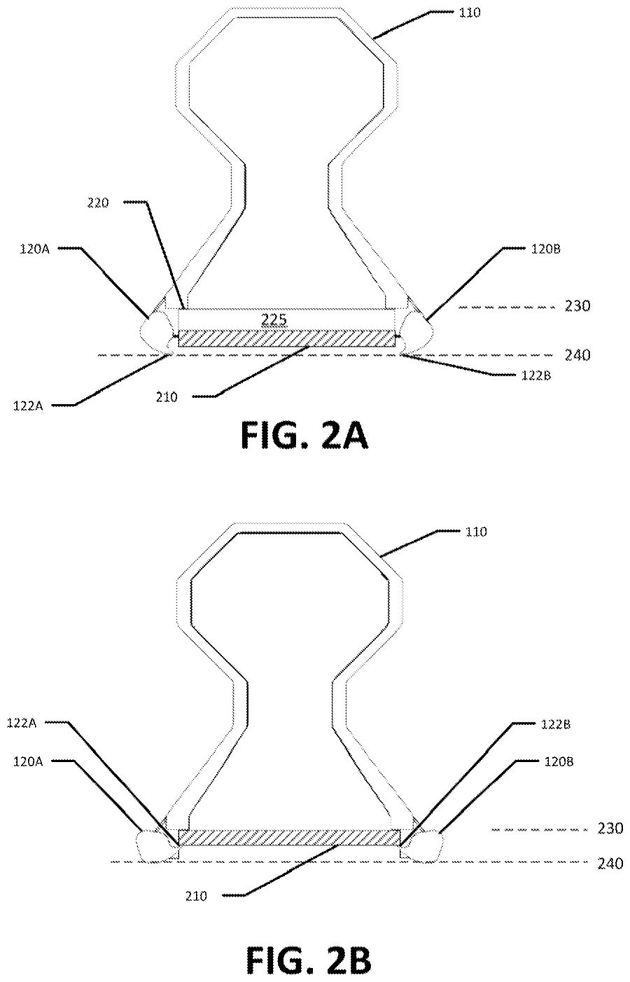

FIG. 2A illustrates a cross section of a tool with fingers in a first orientation in accordance with one or more embodiments of the present disclosure. The cross section may be, for example, at a plane indicated by reference number 150 in FIG. 1. The cross section illustrated in FIG. 2A includes the tool body 110 and two fingers 120A and 120B. The tool body 110 includes a cavity 225 configured to accept a semiconductor device 210. FIG. 2A illustrates a tool 100 with fingers 120A, 120B in a first orientation, which may be referred to as an open orientation. The open orientation may be configured to allow the tool 100 to be placed over a semiconductor device 210. As the tool 100 is aligned over the semiconductor device 210, the semiconductor device is aligned with the cavity 225. A socket is not depicted, but a plane 240 may represent a PCB or another surface that may resist or oppose the, as illustrated, downward motion of tool 100. While the figure depicts the plane 240 below a tool 100, it will be appreciated that “downward” is in reference to the figure and that the tool could be used in any direction, which may then substitute “downward” for another respective direction. The resistance or opposition at plane 240 will cause the fingers 120A and 120B to rotate from a first orientation to a second orientation, the second orientation may be that of the orientation of the fingers 120 illustrated in FIG. 2B. As also illustrated in FIG. 2B, the rotation of the fingers 120A and 120B cause the fingers 120A and 120B to grasp the semiconductor device 210. The rotation of the fingers 120 into the second position may lift the semiconductor device 210 into cavity 225, which may include removing or loosening a semiconductor device 210 from a socket. The semiconductor device 210 may be lifted into the cavity until a first portion, such as a top portion, of the semiconductor device 210 may contact a first portion 220 of tool body 110 at cavity 225 at plane 230.

While FIG. 2A illustrates a cross section, such as along plane 150 of FIG. 1, it will be readily appreciated that this first portion 220 of tool body 110 may extend around the bottom of tool body 110 at cavity 225 to stop semiconductor 210's advance into cavity 225. The first portion of the semiconductor device 210 making contact with a first portion 220 of a tool body 110 may be the entirety of the top of the semiconductor device, may be around the edge of the semiconductor device 210, or may configured to make contact with the top of the semiconductor device in a noncontinuous manner. In various embodiments not illustrated, the first portion 220 may include bumps, stops, or other protrusions configured to stop a semiconductor's advance into a cavity 225, including flexible or compression protrusions that may cushion the semiconductor's advancement into the cavity.

In FIG. 2A the cavity 225 is inside the tool 100. The cavity 225 is configured with a size that corresponds to one or more semiconductor devices 210 to be installed or removed by tool 100. The cavity 225 may be sized to have a clearance around the sides of a semiconductor device that allows for the fingers 120 to rotate and grasp the edges of the semiconductor device 210. A clearance between an edge of the cavity 225 and a corresponding edge of a semiconductor device 210 may be less than 0.005 inches.

In various embodiments, a tool 100 may be configured to remove more than one semiconductor device 225 at once, and it will readily be appreciated that the fingers 120 may be of different sizes to accommodate different size semiconductor devices 225 to be removed, such as different widths or lengths, which may include more than one finger 120 per side or one or more fingers in the interior of the tool 100, such as where cavity 225 is illustrated.

FIG. 2B illustrates a cross section of a tool with fingers in a second orientation in accordance with one or more embodiments of the present disclosure. The cross section may be, for example, at a plane indicated by reference number 150 in FIG. 1. The fingers 120A and 120B are illustrated in FIG. 2B to be in a second orientation after the fingers 120A and 120B have rotated and/or lifted the semiconductor device 210 into cavity 225 (not depicted in FIG. 2B as the semiconductor 210 may fill the cavity 225). The second orientation may be referred to as a grasping orientation, which may refer to the fingers 120 grasping the semiconductor device 210 to hold it in place in the tool 100. Each finger 120A and 120B is configured to have a finger extension 122 that grasps the edge of semiconductor device 210. The finger extension 122 may be configured to grasp a semiconductor device 210 configured with a pin grid array at an outer portion of an underside of a semiconductor device 210 between an edge of the semiconductor device 210 and the first pin or rows of pins on the underside of the semiconductor device 210. Such grasping may allow for an even distribution of pressure to be applied to the underside of a semiconductor device 210 to remove it from a socket while evenly applying pressure in a manner that does not bend or damage the semiconductor device 210 or any of the pins of the pin grid array.

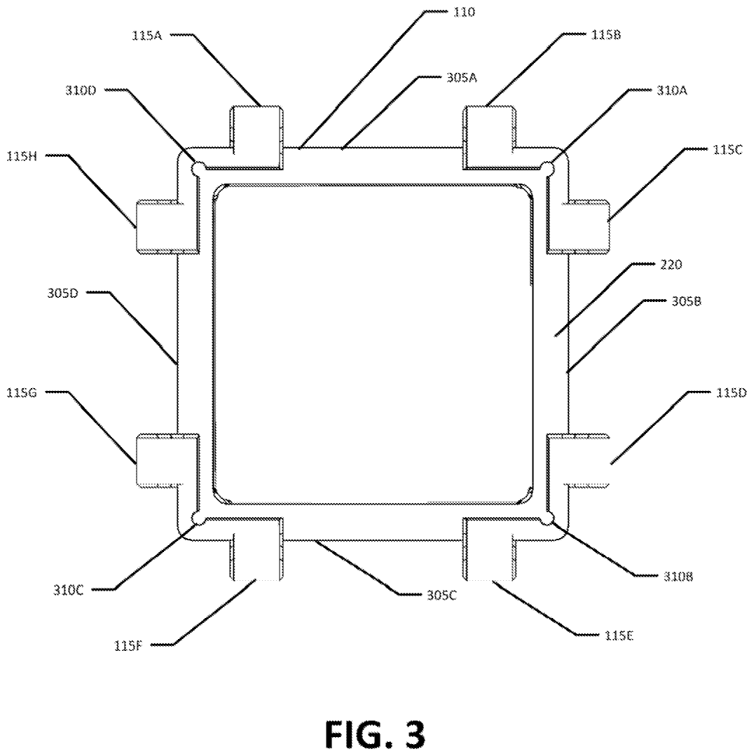

FIG. 3 illustrates a bottom view of a tool body 110 in accordance with one or more embodiments of the present disclosure. The tool body 110 of FIG. 3A omits fingers 120, though it will be readily appreciated where the fingers 120 are located in an assembled tool 100. The bottom view of tool body 110 includes four tool body sides 305A, 305B, 305C, and 305D. Each of the tool body sides 305 is associated with a pair of tool body projections 115 and a finger 120 (not illustrated). The tool body 110 of FIG. 3 illustrates four pairs of tool body projections where each pair would be associated with a finger 120. For example, a first pair is tool body projections 115A and 115B on a first tool body side 305A, a second pair is tool body projections 115C and 115D on a second tool body side 305B, a third pair is tool body projections 115E and 115F on a third tool body side 305C, and a fourth pair is tool body projections 115G and 115H on a fourth tool body side 305D. The tool body projections associated with each corner (e.g., 115B and 115C) may be connected on the tool body 110, and each conner may include a chamber 310. The tool body 110 may also include a first portion 220, which may be the bottom of the tool body 110 at plane 230 for contacting a surface of a semiconductor device 225.

A chamber 310 may be included at each corner of the cavity 225 to correspond to a corner of a semiconductor 210. A chamber 310 may provide for additional room for a corner to be inserted into cavity 225 without interference. In various embodiments, which may depend on the material, the chamber 310 may allow for some flex or expansion of the tool body 110 around the cavity 225 as a semiconductor device 210 is inserted into the cavity 225. In various embodiments, a semiconductor device 210 may have more or fewer than 4 sides and, as will be readily appreciated, the tool body 110 may be configured to have the same number of sides that the semiconductor device has (e.g., 3 sides, 5 sides, 6 sides, etc.).

The first portion 220 may be a bottom of the tool body 110 and may provide a stop against a top of a semiconductor device inserted into a cavity 225 of a tool body 110. As illustrated in FIG. 3, the first portion 220 may extend around the tool body 110.

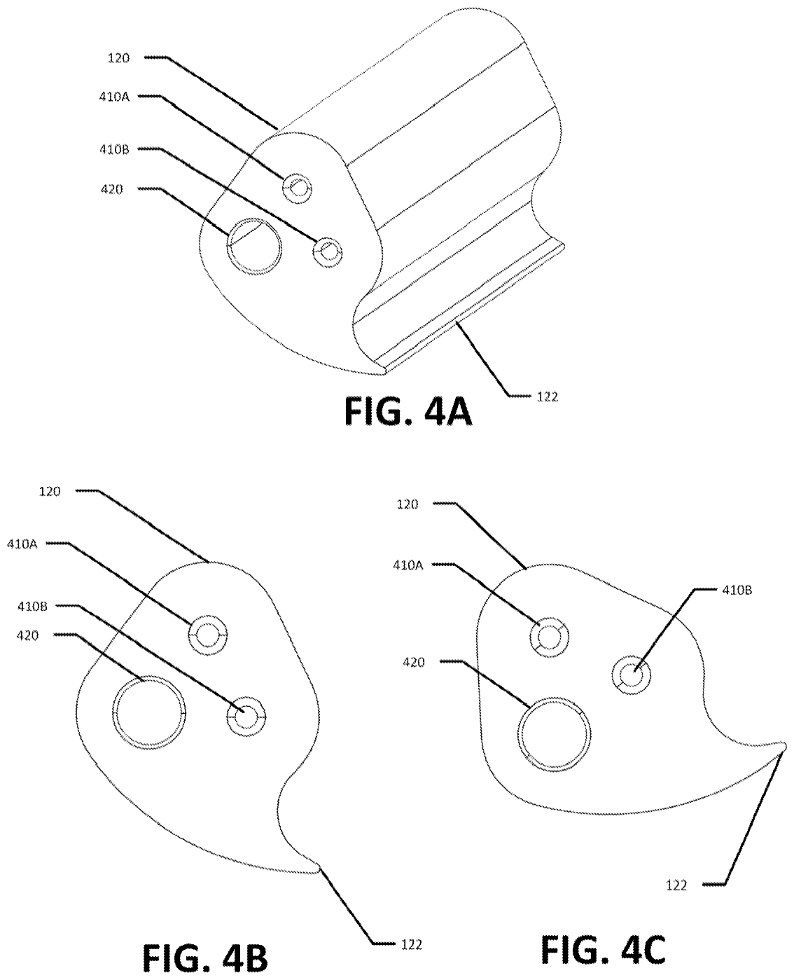

FIG. 4A illustrates a finger 120 from a first perspective in accordance with one or more embodiments of the present disclosure. The finger 120 may include a first aperture 410A, a second aperture 410B, and a third aperture 420. The first aperture 410A and second aperture 410B may each be configured with a bevel. Alternatively, the first aperture 410A and second aperture 410B may be configured as indentations. The first aperture 410A and second aperture 410B may be configured as, respectively, a first stop and a second stop that as associated with a stopping device described further herein to stop the rotation of the finger 120 at, respectively, a first orientation and a second orientation, which are depicted in FIGS. 2A and 2B. The rotation of the finger 120 may be about a pivot point associated with a pivot that may be inserted through aperture 420. The pivot inserted through aperture 420 may include, for example, a rod or a dowel that may run the length of the aperture 430 through the finger 120 or may be run one or both sides of finger 120.

FIG. 4B illustrates a first end of a finger 120 in a first orientation in accordance with one or more embodiments of the present disclosure. As illustrated in FIG. 4B, the finger 120 may be oriented in a first position based on one of the apertures 410A, 410B and a pivot associated with aperture 420. The first orientation illustrated in FIG. 4B may be associated with an open orientation that allows for a semiconductor device 210 to pass into a cavity 225 of a tool 100, such as in FIG. 2A.

FIG. 4C illustrates a first end of a finger in a second orientation in accordance with one or more embodiments of the present disclosure. As illustrated in FIG. 4B, the finger 120 may be oriented in a second position based on one of the apertures 410A, 410B and a pivot associated with aperture 420. The second orientation illustrated in FIG. 4C may be associated with an grasping orientation that allows for a semiconductor device 210 to be grasped in a cavity 225 of a tool 100, such as in FIG. 2B.

In various embodiments a finger 120 may be made out of one or more materials, such as plastic and/or stainless steel. In various embodiments, each of the apertures 410A, 410B, 420 may include a liner that may be made of a different material than the finger 120.

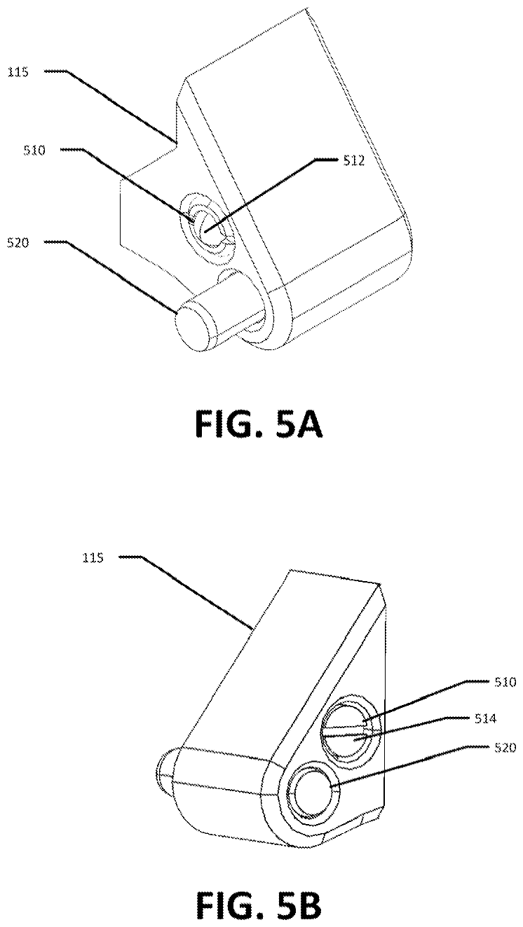

FIG. 5A illustrates a tool body projection 115 from a first perspective in accordance with one or more embodiments of the present disclosure. The tool body projection 115 may include one or more apertures that may contain, for example, a plunger 510 and a pivot 520. The plunger 510 may extend from a first aperture, and the pivot may extend from the second aperture.

FIG. 5B illustrates a tool body projection 115 from a second perspective in accordance with one or more embodiments of the present disclosure. This second perspective illustrates the plunger 510 and the pivot 520 from a second side of a tool body projection 115. In various embodiments, the pivot 520 may be a pin and/or a dowel, which may be pressed into the tool body projection 115 and the associated finger 120. In various embodiments, a pivot 520 may be sized to run through the entirety of a finger 120, such as aperture 420 as well as through one or more tool body projections 115 associated with the finger 120. Alternatively, a pivot 520 may be sized to run through a portion of a finger 120 as well as an associated tool body projection 115, and thus, in some embodiments, each tool body projection 115 associated with a finger 120 may have its own pivot 520 that is sized to run through the tool body projection 115 and a portion of a finger 120, such as a portion of an aperture 420.

In various embodiments, such as when a tool body 110 may be 3D printed, a pivot 520 may be a portion of the tool body 110. In such an embodiment, the pivot 520, as a part of the tool body projection 115, may be fixed with respect to the tool body projection 115 but may allow a finger 120 to rotate on the pivot 520.

In various embodiments, such as when a tool body 110 may be 3D printed, a plunger 510 may be a portion of the tool body 110. In such an embodiment, the plunger 510, as a part of the tool body projection 115, may not be adjusted but instead be fixed with the end of the plunger 510 associated with a finger 120 comprising one or more extensions, such as a ball or bump. The plunger 510 may not have adjustable tension, but it may act as a stop for rotation in conjunction with two or more aperture 410 of a finger 120.

As illustrated in FIGS. 5A, 5B, a plunger 510 may include a tensioning device. The tensioning device may allow for the plunger 510 to have different settings. For example, a set screw 514 on one side of the plunger 510, such as that of FIG. 5B, may allow for the setting of a pressure that other side of the plunger 510, such as that of FIG. 5A, will exert. The setting of the pressure may be increased or decreased with the rotation of the set screw 514. An end of the plunger, such as in FIG. 5A, is associated with a finger 120, and the plunger 510 may include a tip 512, such as a ball, that will be associated with two or more apertures (e.g., 410A, 410B), which may each be associated with an orientation of the fingers. When a finger 120 rotates, such as about a pivot 520, the finger may use the plunger 510 in conjunction with an aperture 410A, 410B to stop the rotation. For example, the tip 512 is configured to couple and/or engage with an aperture 410A, 410B to stop the rotation of the corresponding finger 120 and/or to maintain the finger 120 in a respective position. Subsequent rotation, such as to an open configuration from a grasping configuration, may require the finger to overcome the resistance of the spring of the plunger 510 in order to rotate to another orientation. While the figures herein illustrate two orientations, it will readily be appreciated that a tool 100 may include more than two orientations by increasing the number of apertures 410 associated with a plunger 510.

In various embodiments not illustrated, a finger 120 may include one or more configurations to assist with a user manually adjusting an orientation. A first configuration may include an aperture in an exterior portion of a finger 120 that may allow for a tool, such as a lever, Allen wrench, or the like, to be inserted into the aperture such that a user may rotate the finger 120 in a desired direction, such as from a second orientation for grasping for a first orientation for being open. Another configuration may include an exterior portion of a finger 120 including an extruding lever, which may be similarly used by a user to cause a finger to rotate from a second orientation for grasping for a first orientation for being open.

In various embodiments not illustrated, the tool 100 may include a button in the tool body 110 that may include one or more linkages to each of the plungers 510 to cause the plungers to release or more inward into a tool body projection 115 to allow for a finger 120 to cause a finger to rotate from a second orientation for grasping for a first orientation for being open. This rotation may be due to the pressure provided by a plunger 510 being released when the plunger 510 is released or moved inward, which may cause a finger 120 to rotate due to gravity and/or the weight of a semiconductor device 210.

In various embodiments, the tool body 110 may include one or more openings to allow for a user to insert an extensions (e.g., a lever, screwdriver, Allen wrench, etc.) into the opening to apply pressure to a top side of a semiconductor device 210. This may allow for a user to assist with removing a semiconductor device removed by a tool 100 should the semiconductor device 210 not fall out of its own accord, such as after the fingers 120 have been oriented to a first or open orientation.

In various embodiments, a finger 120 and/or tool body 110 may include one or more protrusions (e.g., lever, rod, or the like) protruding from the finger 120 or the tool body 110. The one or more protrusions may provide additional leverage, such as additional leverage for overcoming a retention force of the pins of a chip. The one or more protrusions may be on one ro more exterior surfaces of a finger 120 and/or tool body 110 and may include one or more linkages, changes in finger shape and size, and/or variations in tool body shape and size.

Having generally described several embodiments of a tool 100, example operations associated will now be described in accordance with several example embodiments.

### Example Operations

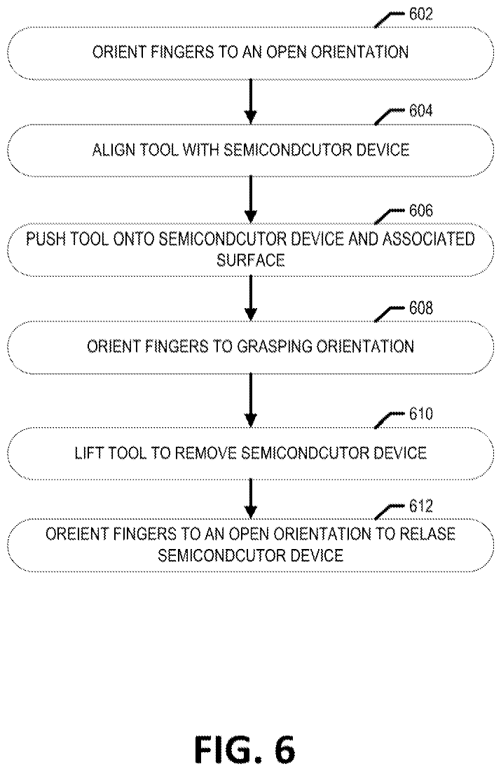

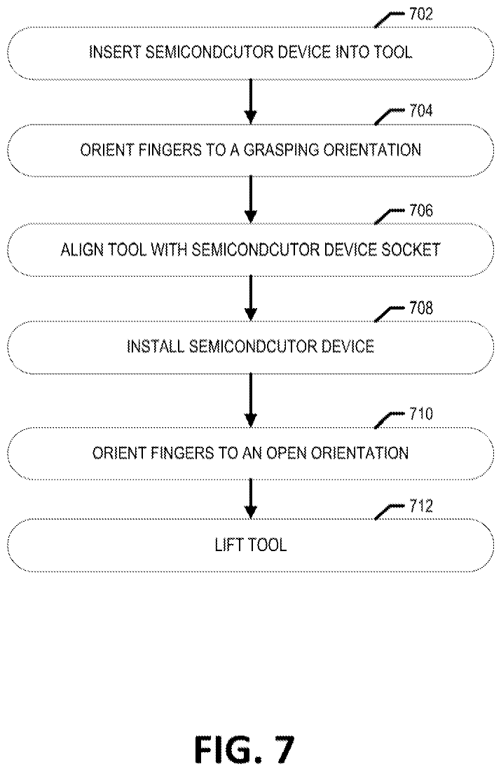

In some example embodiments, a tool 100 may be used to install and/or remove a semiconductor device. FIGS. 6 and 7 illustrate flowcharts associated with various operations, including operations performed with a tool 100. The various operations described in the flowcharts herein may use an embodiment with a tool 100 to provide examples of one or more operations. While the following description includes multiple operations, it is readily appreciated that some of the following operations may be omitted and that additional operations may be included. As is also readily appreciated, some of these operations may be repeated. Additionally, the order of operations should not be interpreted as limiting as the order of these operations may be varied.

FIG. 6 illustrates a flow chart according to an example method for removing a semiconductor device in accordance with one or more embodiments of the present disclosure. The flow chart of FIG. 6 includes multiple operations, some of which may be performed in a different order than illustrated or omitted in their entirety.

At operation 602, orient fingers 120 to an open orientation. A user, using the tool 100, may orient the fingers 120 to a first orientation or position, which may be an open orientation. In the open orientation, such as illustrated in the embodiment of FIG. 2A, the fingers may be oriented to allow a user to align the tool 100 with a semiconductor device 210 such that the semiconductor device 210 may be inserted into the tool the fingers 120 obstructing the insertion of the semiconductor device.

At operation 604, align tool 100 with semiconductor device 210. The tool 100 may be aligned with a semiconductor device 210 to allow for the tool 100 to be lowered down above the semiconductor device 210 and be pushed on the semiconductor device 210. In various embodiments where the semiconductor device 210 has four sides, the tool body sides 305 are aligned with the sides of the semiconductor device 210. In various embodiments, a semiconductor device 210 may include a notch, a guide, a pin, or other alignment feature and the tool 100 may have an alignment feature accommodation, such as but not limited to a cavity, cutout, or a pin. The alignment feature of the semiconductor device and the alignment feature accommodation of the tool 100 may be aligned.

At operation 606, push tool onto semiconductor device. A user, after having aligned the tool 100 with the semiconductor device 210, may apply pressure to the tool 100, which may cause the tool 100 to be lowered onto the semiconductor device 210 and a surface (e.g., 240).

At operation 608, orient fingers 120 to grasping orientation. The pressure may cause the fingers 120 to rotate from a first orientation, such as an open orientation, to a second orientation, such as a grasping orientation. In rotating between the first and the second orientation, the fingers 120 may pivot and one or more finger edges may contact a first plane, such as a bottom plane, of the semiconductor device 210.

At operation 610, lift tool 100 to remove semiconductor device 210. The contact with the bottom plane of the semiconductor device 210 may cause the semiconductor device to be removed or loosened from, for example, a socket where the semiconductor device 210 may have been installed or mounted. A user may life the tool 100 to remove the semiconductor device 210 from the socket.

At operation 612, orient fingers 120 to an open orientation to release semiconductor device 210. After having removed the semiconductor device 210, the user may release the semiconductor device 210 from the tool 100 by orienting the fingers 120 to an open orientation, which may be a first orientation or open orientation from the grasping orientation or second orientation. This orienting of the fingers 120 may include rotating the fingers 120 about their pivots. In various embodiments, this orienting may be performed by a user sequentially inserting a lever or wrench into an aperture of each finger and using the lever or wrench to apply a rotational torque that will overcome the tension of a plunger. Alternatively, various embodiments may include a finger protrusion or exterior protrusion, which may be a lever, rod, or the like, protruding outwardly from the finger 120 to allow for a user to rotate the finger 120 by applying pressure. Such a finger protrusion or exterior protrusion may be on an exterior surface of a finger 120.

FIG. 7 illustrates a flow chart according to an example method for installing a semiconductor device in accordance with one or more embodiments of the present disclosure. The flow chart of FIG. 7 includes multiple operations, some of which may be performed in a different order than illustrated or omitted in their entirety.

At operation 702, insert semiconductor device 210 into tool 100. A user using a tool 100 to install a semiconductor device 210 may first insert the semiconductor device 210 into the tool 100. If the tool 100 has its fingers 120 in a grasping orientation such that the fingers 120 may impede the insertion of the semiconductor device 210, the user may prior to inserting the semiconductor device 210 orient the fingers 120 to an open orientation.

At operation 704, orient fingers 120 to a grasping orientation. After the semiconductor device 210 has been inserted into the tool 100, the fingers of the tool 100 may be oriented to a grasping orientation. In the grasping orientation the tool 100 may hold the semiconductor device 210 in place.

At operation 706, align tool 100 with semiconductor device socket. A user may align the tool 100 holding the semiconductor device 210 with a semiconductor device socket that the semiconductor device 210 is to be installed in.

In various embodiments, a semiconductor device 210 may include a notch, a guide, a pin, or other alignment feature and the semiconductor device socket may have an alignment feature accommodation, such as but not limited to a cavity, cutout, or a pin. The alignment feature of the semiconductor device and the alignment feature accommodation of the semiconductor device socket may be aligned.

At operation 708, install semiconductor device 210. Having aligned the semiconductor device 210 in the tool 100, a user may use the tool 100 to install the semiconductor device 210 in the semiconductor device socket. In various embodiments, installing the semiconductor device 210 may include pushing the tool 100 downward such that a plurality of pins of the semiconductor device 210 may be inserted into a semiconductor device socket.

In various embodiments, a tool body 110 of a tool 100 may include an aperture or opening to allow a user to insert a finger or device to pressure down on a top surface of a semiconductor device 210. By doing so, the semiconductor device 210 may be dislodged from a cavity 225 of the tool 100 in addition to, or alternatively, be pressed into the semiconductor device socket.

At operation 710, orient fingers 120 to an open orientation. A user may orient the fingers 120 to an open position from a grasping position such that when the tool 100 is lifted away from the semiconductor device socket the tool 100 may be removed while leaving the semiconductor 210 installed in the semiconductor device socket.

At operation 712, lift tool 100. The user may lift the tool 100 away from the semiconductor device socket while leaving the semiconductor device 100 installed.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination. Similarly, while operations are depicted in the drawings in a particular order, this should not be understood as requiring that such operations be performed in the particular order shown or in sequential order, or that all illustrated operations be performed, to achieve desirable results.

Many modifications and other embodiments of the invention set forth herein will come to mind to one skilled in the art to which the invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A tool comprising:
a tool body comprising a plurality of tool body sides and a plurality of tool body projections, wherein each of the plurality of tool body sides includes at least one tool body projection;
a plurality of fingers, wherein each of the plurality of fingers is pivotally coupled to one or more tool body projections via one or more pivots; and
wherein each of the plurality of fingers is configured to be moveable via the pivot between a first orientation and a second orientation, the first orientation is associated with a first stop on the associated finger; and the second orientation is associated with a second stop on the associated finger.

2. The tool of claim 1, wherein each tool body side includes two tool body projections associated with one of the plurality of fingers.

3. The tool of claim 1, wherein each tool body side is associated with two of the plurality of fingers.

4. The tool of claim 1, wherein each pivot extends through a length of a finger to connect one of the plurality of fingers and at least two tool body projections.

5. The tool of claim 1, wherein one or more fingers include an exterior protrusion configured to rotate the finger.

6. The tool of claim 1, wherein one or more fingers includes a cavity configured for use with a second tool to rotate the finger.

7. The tool of claim 1, wherein the first stop and the second stop of each finger are configured for use with one of a plurality of plungers.

8. The tool of claim 1, wherein each of the first stop and the second stop of each finger comprise an aperture.

9. The tool of claim 7, wherein each plunger comprises a spring, and wherein the spring of each plunger is configured to be adjusted to increase a spring tension of the associated plunger.

10. The tool of claim 9, wherein the spring of each plunger is configured to be adjusted by an associated set screw.

11. The tool of claim 1, wherein the tool body includes an interior cavity comprised of a plurality of corners, and wherein each of the corners is configured to have a corner chamber configured to accommodate a semiconductor device corner.

12. The tool of claim 1, wherein the tool body is hollow.

13. The tool of claim 1, wherein the plurality of tool body sides comprises four tool body sides.

14. The tool of claim 13, wherein the plurality of fingers comprises one finger associated with each of the tool body sides.

15. The tool of claim 1, wherein each of the fingers comprises a first finger extension configured engage a first surface to allow for the finger to rotate.

16. The tool of claim 15, wherein each of the fingers is further configured to be moveable via the pivot associated with the finger in response to the associated finger extension engaging the first surface.

17. A method for removing a semiconductor device:
providing a tool comprising:
a tool body comprising a plurality of tool body sides and a plurality of tool body projections, wherein each of the plurality of tool body sides includes at least one tool body projection;
a plurality of fingers, wherein each of the plurality of fingers is pivotally coupled to one or more tool body projections via one or more pivots; and
wherein each of the plurality of fingers is configured to be moveable via the pivot between a first orientation and a second orientation, the first orientation is associated with a first stop on the associated finger; and the second orientation is associated with a second stop on the associated finger;
aligning the tool with the semiconductor device;
pushing the tool onto the semiconductor device and an associated surface;
orienting, in response to pushing the tool, each of the fingers to a grasping orientation, wherein the fingers in the grasping orientation include the fingers grasping the semiconductor device; and
removing the semiconductor device.

18. The method for removing the semiconductor device of claim 17 further comprising:
moving, after removing the semiconductor device, the fingers to an open orientation to release the semiconductor device from the tool.

19. A method for installing a semiconductor device:
providing a tool comprising:
a tool body comprising a plurality of ha tool ndle body sides and a plurality of tool body projections, wherein each of the plurality of tool body sides includes at least one tool body projection;
a plurality of fingers, wherein each of the plurality of fingers is pivotally coupled to one or more tool body projections via one or more pivots; and
wherein each of the plurality of fingers is configured to be moveable via the pivot between a first orientation and a second orientation, the first orientation is associated with a first stop on the associated finger; and the second orientation is associated with a second stop on the associated finger;
inserting the semiconductor device into the tool;
moving the fingers to a grasping orientation;
aligning the tool with a socket; and
installing the semiconductor device into the socket.

20. The method for installing the semiconductor device of claim 19 further comprising:
moving, after installing the semiconductor device, the fingers to an open orientation.
